(19) United States
(12) Patent Application Publication
(10) Pub. No.: US 2021/0116483 A1
(43) Pub. Date: Apr. 22, 2021

(54) CURRENT MONITORING SYSTEM AND OUTPUT CURRENT MONITORING DEVICE

(71) Applicant: MING-TSUNG CHEN, Taipei City (TW)

(72) Inventor: MING-TSUNG CHEN, Taipei City (TW)

(21) Appl. No.: 16/659,789

(22) Filed: Oct. 22, 2019

(51) Int. Cl. G01R 19/25; H02J 3/38; H02J 13/00; G01R 31/40; G01R 15/18

(52) U.S. Cl. CPC G01R 19/2513; H02J 3/383; G01R 15/18; G01R 31/40; H02J 13/0006

(57) ABSTRACT

A current monitoring system and an output current monitoring device are provided. The output current monitoring device includes a control module, a communication module, a first hub module, a second hub module, a current sensor module, and a switch module. The switch module is disposed between the power generation devices and the power collecting device. The current sensor module is disposed at one side of the switch module adjacent to the power collecting device for detecting a plurality of current values of the power generation devices. The control module receives a modulation signal of the server to adjust a turn-on state or a turn-off state of the switch module for determining a total power that the power generation device provides to the power collecting device.

### FIELD OF THE DISCLOSURE

The present disclosure relates to a current monitoring system and an output current monitoring device, and more particularly to a current monitoring system and an output current monitoring device controlled by a remote server.

### BACKGROUND OF THE DISCLOSURE

Since traditional solar power plants generally do not have IoT related equipment, they cannot quickly achieve a power modulation requirement for each area in a power grid of a power company.

Therefore, it is an important subject in the industry to provide a current monitoring system capable of quickly adjusting a total power of a plurality of power generating devices, and having low cost and simple configurations.

### SUMMARY OF THE DISCLOSURE

In response to the above-referenced technical inadequacies, the present disclosure provides an output current monitoring device electrically connected to a plurality of power generation devices and a power collecting device. The output current monitoring device includes a control module, a communication module, a first hub module, a second hub module, a current sensor module, and a switch module. The communication module is electrically connected to the control module. The first hub module is electrically connected to the control module. The second hub module is electrically connected to the control module. The current sensor module is electrically connected to the second hub module. The switch module is electrically connected to the first hub module. The switch module is electrically connected to the power generation devices and the power collecting device. The switch module is disposed between the power generation devices and the power collecting device. The current sensor module is disposed at one side of the switch module adjacent to the power collecting device for detecting a plurality of current values of the power generation devices. The control module communicates with a server through the communication module, and receives a modulation signal of the server. The control module adjusts a turn-on state or a turn-off state of the switch module to determine a total power that the power generation device provides to the power collecting device.

In certain embodiments, the present disclosure provides a current monitoring system communicating with a server. The current monitoring system includes four power generation devices, an output current monitoring device, and a power collecting device.

The output current monitoring device is electrically connected to the four power generation devices. The output current monitoring device includes a control module, a communication module, a first hub module, a second hub module, a current sensor module, and a switch module. The communication module is electrically connected to the control module. The communication module communicates with the server. The first hub module is electrically connected to the control module. The second hub module is electrically connected to the control module. The current sensor module is electrically connected to the second hub module. The current sensor includes four current sensors. The switch module includes four switch units. The four switch units of the switch module are electrically connected to the first hub module. The power collecting device is electrically connected to the output current monitoring device for transmitting the power provided by the four power generation devices to an electrical grid. The four switch units of the switch module are electrically connected to the four power generation devices, respectively. The four switch units of the switch module are respectively connected to the power collecting device through four power cables. The four switch units of the switch module are respectively disposed between the four power generation devices and the power collecting device. The four current sensors are respectively disposed at an outer side of the four power cables. The current monitoring system adjusts turn-on states or turn-off states of the four switch units of the switch module of the output current monitoring device based on a power providing data provided by the server.

Therefore, the current monitoring system and the output current monitoring device of the present disclosure effectively modulates the total power based on the power providing data. In addition, the output current monitoring device is disposed between a plurality of power generating devices and the electrical grid in a simple manner, so that an installation cost thereof can be effectively reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a block diagram of a current monitoring system of a first embodiment of the present disclosure.

FIG. 2 is a block diagram of an output current monitoring device in FIG. 1.

FIG. 3 is a schematic diagram of power supply information provided by a server of FIG. 1.

FIG. 4 is a block diagram of a current monitoring system of a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

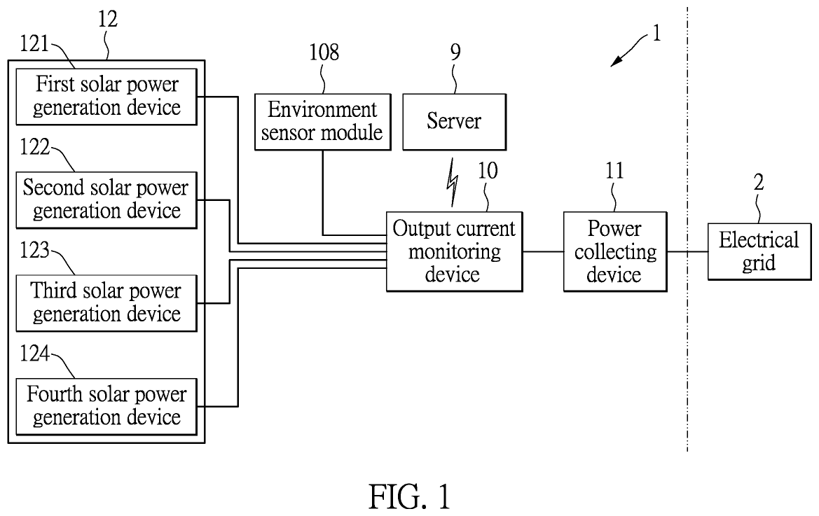

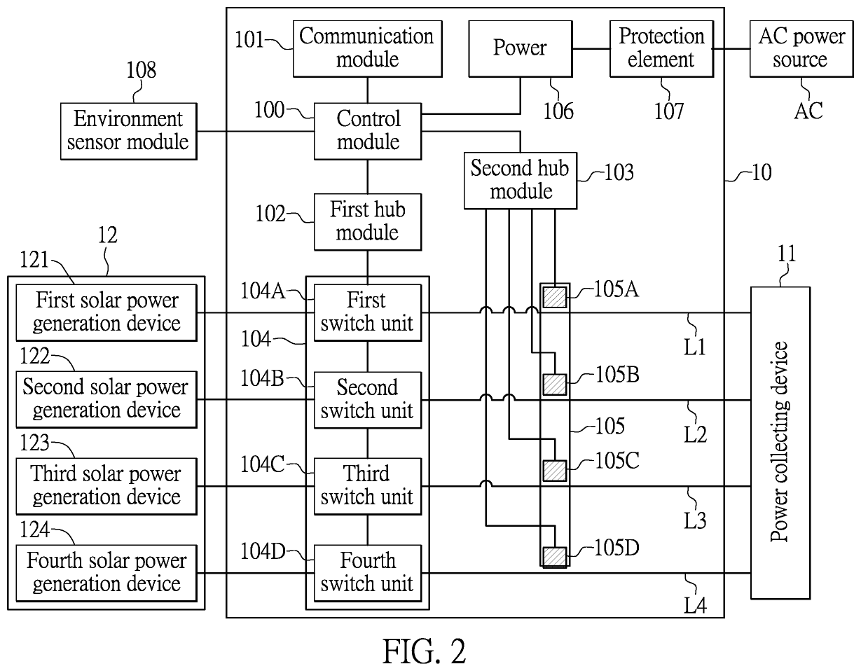

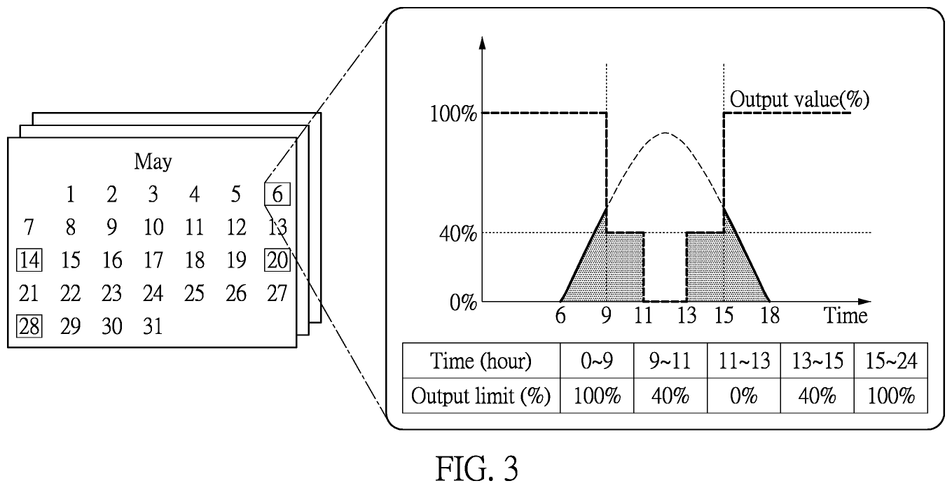

Referring to FIG. 1, FIG. 2, and FIG. 3, FIG. 1 is a block diagram of a current monitoring system of a first embodiment of the present disclosure. FIG. 2 is a block diagram of an output current monitoring device in FIG. 1. FIG. 3 is a schematic diagram of power supply information provided by a server of FIG. 1.

A current monitoring system 1 communicates with a server 9. The current monitoring system 1 is electrically connected to an electrical grid 2. The current monitoring system 1 includes an output current monitoring device 10, a power collecting device 11, and a power generation device group 12. The power generation device group 12 includes four power generation devices which respectively are a first solar power generation device 121, a second solar power generation device 122, a third solar power generation device 123, and a fourth solar power generation device 124. In the embodiment, the power generating device group 12 can include a plurality of power generating devices including a solar power generating device, a fuel cell power generating device, a wind power generating device, a hydropower generating device, a geothermal heat generating device, and a thermal power generation device, a biofuel power generation device, a marine energy power generation device or a nuclear power generation device, and is not limited in the present disclosure. The power collecting device 11 receives power of the power generation devices of the power generation device group 12, and modulates the power provided by the power generation devices, such as current stacking or voltage adjustment, for outputting an AC power to the electrical grid 2.

In the embodiment, the output current monitoring device 10 is electrically connected to the power collecting device 11 and the first solar power generation device 121, the second solar power generation device 122, the third solar power generation device 123, and the fourth solar power generation device 124 of the power generation device group 12.

The output current monitoring device 10 includes a control module 100, a communication module 101, a first hub module 102, a second hub module 103, a switch module 104, a current sensor module 105, a power module 106, a protection element 107, and an environment sensor module 108.

The control module 100 is electrically connected to the communication module 101, the first hub module 102, the second hub module 103, and the environment sensor module 108. The first hub module 102 is electrically connected to the switch module 104. The second hub module 103 is electrically connected to the current sensor module 105. The communication module 101 communicates with the server 9. The communication module can be a Wi-Fi communication module, a Bluetooth communication module, a Zigbee communication module, a LoRa communication module, a Sigfox communication module, or a NB-IoT communication module, and is not limited in the present disclosure. The first hub module 102 and the second hub module 103 can be an RS232 serial control module or an RS485 serial control module.

In the embodiment, the current sensor module 105 includes four current sensors 105A-105D. The switch module 104 includes four switch units 104A-104D. The switch module 104 includes a first switch unit 104A, a second switch unit 104B, a third switch unit 104C, and a fourth switch unit 104D. The current sensor module 105 includes a first current sensor 105A, a second current sensor 105B, a third current sensor 105C, and a fourth current sensor 105D. The four switch units 104A-104D are electrically connected to the first hub module 102. The current sensors 105A-105D are electrically connected to the second hub module 103. Each of the current sensors 104A-104D can be an electromagnetic switch or a reed switch, and is not limited in the present disclosure. The first hub module 102 provides an electrical power to the switch units 104A-104D. The second hub module 103 provides an electrical power to the current sensors 105A-105D.

The output current monitoring device 10 further includes a case 109. The material of the case 109 is metal, plastic, or rubber, and is not limited in the present disclosure. Since the control module 100, the communication module 101, the first hub module 102, the second hub module 103, the switch module 104, and the current sensor module 105, the power module 106, and the protection element 107 are disposed in the case 109.

The environment sensor module 108 is disposed at a predetermined location outside of the case 109 for detecting an environment parameter. The environment parameter includes a temperature value, a humidity value, or an ambient brightness value. In other words, the environment sensor module 108 at least includes a temperature sensor, a humidity sensor, and an ambient brightness sensor, and is not limited in the present disclosure. The power collecting device 11 is electrically connected to the switch module 104 of the output current monitoring device 10.

The four switch units 104A-104D of the switch module 104 are respectively connected to the four power generation devices 121-124. The four switch units 104A-104D of the switch module 104 are connected to the power collecting device 11 through four power cables L1-L4. The four switch units 104A-104D of the switch module 104 are respectively disposed between the four power generation devices 121-124 and the power collecting device 11. The four current sensors 105A-105D are respectively disposed at an outer side of the four power cables. In the embodiment, the current sensors 105A-105D are Hall sensors for detecting the current values of the four power cables L1-L4 in an induction manner. The four power cables includes a first power cable L1, a second power cable L2, a third power cable L3, and a fourth power cable L4.

The control module 10 is a central processing unit or a microprocessor, and is not limited in the present disclosure. The server 9 is a remote server or a local server. The server 9 communicates with a regional power control center for receiving a power providing data. The server 9 provides a modulation signal based on the power providing data to the output current monitoring device 10.

In the embodiment, the power module 106 is electrically connected to the control module 100 and an AC power source AC for providing a driving power to the output current monitoring device 10. The power module 106 is an AC to DC convertor. In other embodiments, the power module 106 can be a DC to DC convertor. In other words, the power module is electrically connected to a DC power source.

In addition, since the output current monitoring device 10 is disposed outdoors, the protection element 107 is further disposed between the power module 106 and the AC power source AC for avoiding lightning strikes, a large current, or other accidents. In the embodiment, the protection element 107 is a circuit breaker. The power generation devices 121-124 also can be electrically connected to a power storage device (not shown) for storing electrical power.

Referring to FIG. 3, FIG. 3 is a schematic diagram of power supply information provided by a server of FIG. 1. The power providing data includes a total power output in different time intervals of different days.

The control module 100 communicates with the server 9 through the communication module 101 to receive a modulation signal of the server 9. The control module 100 adjusts a turn-on state or a turn-off state of the switch module 104 for determining a total current of the power generation devices 121-124 provided to the power collecting device 11. The control module 100 determines the total current based on the modulation signal of the server 9 and the current values detected by the current sensors 105A-105D of the current sensor module 105, and determines the total power output. In other words, the control module 100 records a maximum current value of each of the power generation devices to determine a maximum total power output of the power generation devices 121-124 connected to the switch module 104. Therefore, the control module 100 can adjust turn-on states or turn-off states of the switch units 104A-104D based on the current values detected by the current sensors 105A-105D of the current sensor module 105 for outputting the total power corresponding to the modulation signal.

In the embodiment, the power generation devices 121-124 connected to the output current monitoring device 10 can be different power generation devices with different power generation states. The output current monitoring device 10 records maximum current values and minimum current values of each of the power generation devices 121-124, and environment parameters in the same time interval that are detected by the environment sensor module 108. The control module 10 transmits the current values and the environment parameters to the server 9 for a big data analysis. The communication module 101 is a wired communication module or a wireless communication module.

### Second Embodiment

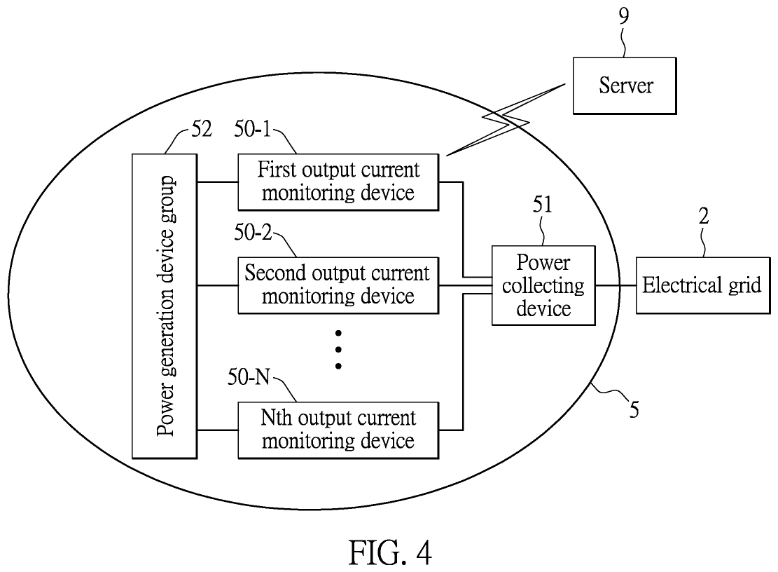

Referring to FIG. 4, FIG. 4 is a block diagram of a current monitoring system of a second embodiment of the present disclosure.

In the embodiment, the current monitoring system 5 includes a power collecting device 51, a power generation device group 52, and a plurality of output current monitoring devices 50-1 to 50-N. The output current monitoring devices 50-1 to 50-N includes a plurality of output current monitoring devices from a first output current monitoring device 50-1 to an Nth output current monitoring device 50-N. The power generation device group 52 includes a plurality of power generation devices (not shown). The power generating device is a solar power generating device, a fuel cell power generating device, a wind power generating device, a hydropower generating device, a geothermal heat generating device, a thermal power generation device, a biofuel power generation device, a marine energy power generation device or a nuclear power generation device, and is not limited in the present disclosure. In the embodiment, each of the output current monitoring device 50-1 to 50-N can be electrically connected to one or more power generation device(s). In other words, total output currents of the power output current monitoring devices 50-1 to 50-N can be different. Electrical power received by the output current monitoring devices are provided to the power collecting device 51 for adjustment, and transmitted to the electrical grid 2.

Each of the output current monitoring device 50-1 to 50-N communicates with the server 9 for receiving respective power providing data. In other words, the server 9 can determine the power providing data of each of the output current monitoring devices 50-1 to 50-N based on power providing states of the power generation devices connected to the output current monitoring devices 50-1 to 50-N.

In conclusion, the current monitoring system and the output current monitoring device of the present disclosure effectively modulates the total power based on the power providing data. In addition, the output current monitoring devices are disposed between a plurality of power generating devices and the electrical grid in a simple mariner, so that an installation cost thereof can be effectively reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An output current monitoring device electrically connected to a plurality of power generation devices and a power collecting device, the output current monitoring device comprising:
a control module;
a communication module electrically connected to the control module;
a first hub module electrically connected to the control module;
a second hub module electrically connected to the control module;
a current sensor module electrically connected to the second hub module; and
a switch module electrically connected to the first hub module, the switch module being electrically connected to the power generation devices and the power collecting device, the switch module being disposed between the power generation devices and the power collecting device, and the current sensor module being disposed at one side of the switch module adjacent to the power collecting device for detecting a plurality of current values of the power generation devices;
wherein the control module communicates with a server through the communication module, and receives a modulation signal of the server, and the control module adjusts a turn-on state or a turn-off state of the switch module to determine a total power that the power generation device provides to the power collecting device.

2. The output current monitoring device of claim 1, further comprising:
a case, the control module, the communication module, the first hub module, the second hub module, the current sensor module, and the switch module being disposed in the case.

3. The output current monitoring device of claim 1, further comprising:
a power module electrically connected to the control module and an AC power source for providing a driving power to the output current monitoring device, the power module being an AC to DC converter.

4. The output current monitoring device of claim 1, wherein the switch module includes a first switch unit, a second switch unit, a third switch unit, and a fourth switch unit, the current sensor module includes a first current sensor, a second current sensor, a third current sensor, and a fourth sensor, and the power generation devices includes a first power generation device, a second power generation device, a third power generation device, and a fourth power generation device, and wherein the first switch unit is electrically connected to the first power generation device and the power collecting device, the second switch unit is electrically connected to the second power generation device and the power collecting device, the third switch unit is electrically connected to the third power generation device and the power collecting device, the fourth switch unit is electrically connected to the fourth power generation device and the power collecting device, the first current sensor is disposed at one side of the first switch unit that is adjacent to the power collecting device, the second current sensor is disposed at one side of the second switch unit that is adjacent to the power collecting device, the third current sensor is disposed at one side of the third switch unit that is adjacent to the power collecting device, and the fourth current sensor is disposed at one side of the fourth switch unit that is adjacent to the power collecting device.

5. The output current monitoring device of claim 4, wherein the first current sensor, the second current sensor, the third current sensor, and the fourth current sensor are Hall sensors.

6. The output current monitoring device of claim 1, wherein the first hub module and the second hub module are serial control modules, and the communication module is a wired communication module or a wireless communication module.

7. A current monitoring system communicating with a server, the current monitoring system comprising:
four power generation devices;
an output current monitoring device electrically connected to the four power generation devices, the output current monitoring device including:
a control module;
a communication module electrically connected to the control module, the communication module communicating with the server;
a first hub module electrically connected to the control module;
a second hub module electrically connected to the control module;
a current sensor module electrically connected to the second hub module, the current sensor including four current sensors; and
a switch module including four switch units, the four switch units of the switch module electrically connected to the first hub module; and
a power collecting device electrically connected to the output current monitoring device for transmitting the power provided by the four power generation devices to an electrical grid;
wherein the four switch units of the switch module are electrically connected to the four power generation devices respectively, the four switch units of the switch module are respectively connected to the power collecting device through four power cables, the four switch units of the switch module are respectively disposed between the four power generation devices and the power collecting device, the four current sensors are respectively disposed at an outer side of the four power cables, and the current monitoring system adjusts turn-on states or turn-off states of the four switch units of the switch module of the output current monitoring device based on a power providing data provided by the server.
